(19) United States
(12) Patent Application Publication
(10) Pub. No.: US 2022/0165998 A1
(43) Pub. Date: May 26, 2022

(54) Lantern Battery Adapter

(71) Applicant: Adam Vincent Hayball, Sylvania, OH (US)

(72) Inventor: Adam Vincent Hayball, Sylvania, OH (US)

(21) Appl. No.: 17/100,839

(22) Filed: Nov. 21, 2020

(51) Int. Cl. H01M 2/20; H05K 1/11; H01M 2/30

(52) U.S. Cl. CPC H01M 2/204; H01M 2220/30; H01M 2/30; H05K 1/112

(57) ABSTRACT

An embodiment of the present invention comprising of a conductive top layer with a plurality of terminals enabling battery connections to be made in series. An insulator middle layer with conductive material extending from the top terminals to the bottom terminals. A conductive bottom layer with a plurality of terminals enabling battery connections to be made to the output terminal or terminals. Output terminal or terminals enabling a load or additional lantern battery adapters to be connected either in series or parallel configuration.

### BACKGROUND OF THE INVENTION

### 1. Field of the Invention

The present invention is in the field of battery adapters and pertains particularly to an article of manufacture for adapting lantern batteries to function in manners and applications other than originally manufactured.

### 2. Discussion of the State of the Art

Lantern batteries both rechargeable such as the PowerSonic PS-650 LS and disposable such as the Duracell MN908 are readily available in the marketplace and provide a source of high-density portable electricity. However, their characteristic of having a nominal rating of 6 volts limits their potential use case scenarios. Batteries with a voltage rating of 12 volts or higher offer several advantages such as lower current draw and a much larger range of applications. Energy density is another area of concern for lantern batteries due to their size and chemical makeup they are not ideal for extended current draw.

Therefore, what is needed to utilize the resource of lantern batteries more effectively is a method of expediently and easily adapting such batteries to a wider range of applications and use cases.

### BRIEF SUMMARY OF THE INVENTION

In accordance with an embodiment of the present invention, a lantern battery adapter, which may be used with two batteries comprising a plurality of soldered battery terminal connections as well as a plurality of output terminals, comprises of a top conductive layer with a series connection between battery terminals and insulated output terminals. A middle layer of insulator material with electrical connections extending from the top layer through the insulator layer and to the bottom layer. A bottom conductive layer with a plurality of battery terminals electrically connected to output terminal or terminals.

Another aspect of the invention involves the use of output terminals to power a load or to be connected with another lantern battery adapter and batteries in series or parallel to create a higher voltage battery bank or increase overall capacity of the bank through parallel connection using either solder or other mechanical methods.

### BRIEF DESCRIPTION OF THE SEVERAL VIEWS OF THE DRAWINGS

FIG. 1 is a top elevation view of an embodiment of an adapter.

FIG. 2 is a bottom elevation view of an embodiment of an adapter.

### DETAILED DESCRIPTION OF THE INVENTION

The inventor provides a unique article of manufacture consisting of conductive material on the top and bottom of an insulator layer with conductive material extending through the insulator layer that creates a circuit allowing lantern batteries to be connected in both series and parallel so that they may form a larger array of cells in variable voltage and current capacity. The present invention is described in enabling detail in the following examples, which may represent more than one embodiment of the present invention.

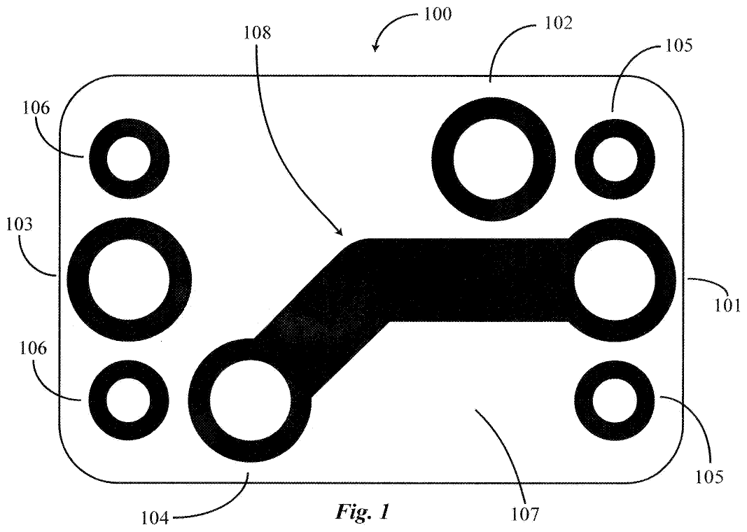

FIG. 1 is a top elevation view of the lantern battery adapter 100 showing circuit traces enabling connection to a 6-volt lantern battery according to an embodiment of the present invention. In this example of the lantern battery adapter 100 shows an electrically conductive terminal connecting to the first batteries negative terminal 101 as well as an electrically conductive terminal connecting to the first batteries positive terminal 102. The second battery has a conductive positive terminal shown at 104 the second batteries negative terminal is shown at 103. This example of the lantern battery adapter 100 shows a plurality of positive voltage output terminals at 105. This example of the lantern battery adapter 100 shows a plurality of negative voltage output terminals at 106. An electrically insulating material is shown at 107. A conductive trace connecting the first batteries negative terminal to the second batteries positive terminal is shown at 108. All of the terminals shown are electrically connected through the insulator layer with a conductive material.

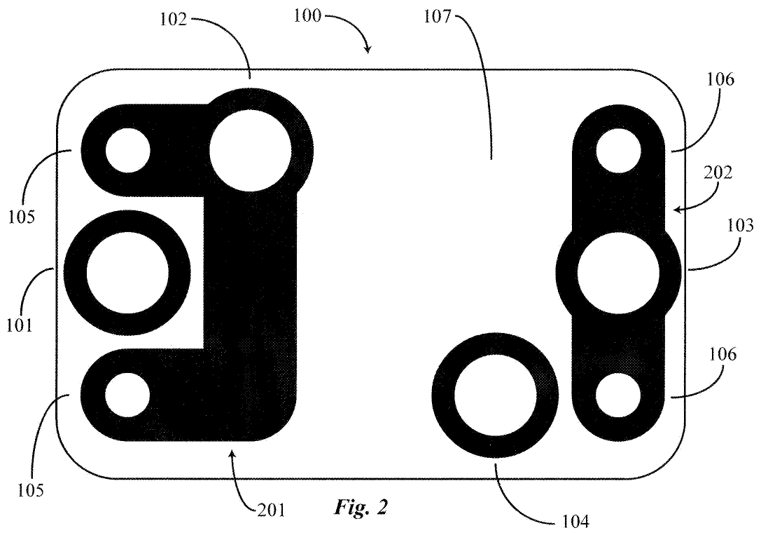

FIG. 2 is a bottom elevation view of the lantern battery adapter 100 showing circuit traces enabling connection to a 6-volt lantern battery according to an embodiment of the present invention. In this example of the lantern battery adapter 100 shows an electrically conductive terminal connecting to the first batteries negative terminal 101 as well as an electrically conductive terminal connecting to the first batteries positive terminal 102. The Second battery has a conductive positive terminal shown at 104 the second batteries negative terminal is shown at 103. This lantern battery adapter 100 shows a plurality of positive voltage output terminals at 105. This lantern battery adapter 100 shows a plurality of negative voltage output terminals at 106. An electrically insulating material is shown at 107. An electrically conductive trace 201 is shown connecting the plurality of positive output terminals 105 to the first batteries positive terminal 102. An electrically conductive trace 202 is shown connecting the plurality of negative output terminals 106 to the second batteries negative terminal 103. All of the terminals shown are electrically connected through the insulator layer with a conductive material.

It will be apparent to one with skill in the art that the lantern battery adapter of the invention may be provided using some or all of the mentioned features and components without departing from the spirit and scope of the present invention. It will also be apparent to the skilled artisan that the embodiments described above are specific examples of a single broader invention which may have greater scope than any of the singular descriptions taught. There may be many alterations made in the descriptions without departing from the spirit and scope of the present invention.

1. A lantern battery adapter, usable with two batteries comprising of:
A conductive top layer;
An insulator middle layer;
A conductive bottom layer;

2. The lantern battery adapter of claim 1, a plurality of soldered terminals enabling battery connections to be made in series.

3. The lantern battery adapter of claim 1, conductive material extending from the top terminals to the bottom terminals.

4. The lantern battery adapter of claim 1, a plurality of soldered terminals enabling battery connections to be made to the output terminal or terminals.

5. The lantern battery adapter of claim 1, output terminal or terminals being soldered or otherwise mechanically connected enabling a load or additional lantern battery adapters to be connected either in series or parallel configuration.
